(19) United States
(12) Patent Application Publication
(10) Pub. No.: US 2007/0236891 A1
(43) Pub. Date: Oct. 11, 2007

(54) Semiconductor device having heat radiation member and semiconductor chip and method for manufacturing the same

(75) Inventor: Kuniaki Mamitsu, Okazaki-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 11/730,360

(22) Filed: Mar. 30, 2007

(30) Foreign Application Priority Data
Apr. 3, 2006 (JP) 2006-101933
Dec. 27, 2006 (JP) 2006-351725

(51) Int. Cl. H05K 7/20

(52) U.S. Cl. 361/718

(57) ABSTRACT

A manufacturing method of a semiconductor device having a semiconductor chip, first and second heat radiation members, and a connection terminal includes: preparing a lead frame having first and second suspended terminals and the connection terminal; bending the suspended terminals; mounting the chip on the first member, press-contacting the first terminal to the first member, and bonding the chip with the connection terminal to the first member; and preparing an assembling jig having a base and a cover, mounting the first member on the base, arranging the second member on the second terminal, pressing the second member with the cover toward the base to parallelize heat radiation surfaces, and bonding the chip and the second member. A distance between the first member and the second terminal is larger than a distance between the first member and the chip.

### CROSS REFERENCE TO RELATED APPLICATIONS

This application is based on Japanese Patent Application No. 2006-101933 filed on Apr. 3, 2006, and No. 2006-351725 filed on Dec. 27, 2006, the disclosures of which are incorporated herein by reference.

### FIELD OF THE INVENTION

The present invention relates to a semiconductor device having a heat radiation member and a semiconductor chip and a method for manufacturing the same.

### BACKGROUND OF THE INVENTION

A semiconductor device having a pair of heat radiation members and a semiconductor chip is disclosed in, for example, Japanese Patent No. 3525832. The heat radiation members are connected to the semiconductor chip thermally and electrically. Each heat radiation member includes a heat radiation surface. Specifically, two semiconductor chips are arranged on a same plane, and the heat radiation members sandwich both semiconductor chips. Each chip includes a main electrode, which is connected to the heat radiation members thermally and electrically with a bonding member such as a solder member. A resin mold covers the device such that the heat radiation surface of each heat radiation member is exposed from the resin mold. Each semiconductor chip is controlled with a signal inputted from an external circuit through a control terminal.

In the above device, the heat radiation members and the control terminal are integrated. However, the thickness of each heat radiation member is different from the thickness of the control terminal. Accordingly, the device is formed from a deformed member. The deformed member is obtained in such a manner that a rolled member is plastically deformed and/or the surface of a metallic plate is cut. Alternatively, the heat radiation members and the control terminal are independently prepared, and then, they are crimped.

In the above device, since the heat radiation members and the control terminal are integrated, the following problems occur.

First, it is necessary to integrate the heat radiation members and the control terminal. Accordingly, when the deformed member is prepared, the rolled metallic member is plastically deformed. Thus, a processing strain caused by the plastic deformation is formed in the deformed member. Thus, the heat radiation member may warp, and deviation from flatness on the heat radiation surface of the heat radiation member becomes high. Further, since the heat radiation members sandwich the semiconductor chip, it is difficult to keep parallelism between the heat radiation surfaces of the heat radiation members.

The deviation from flatness of the heat radiation surface and the parallelism between the heat radiation surfaces affect the heat radiation performance of the heat radiation member. Accordingly, it is required to control the deviation from flatness and the parallelism with accuracy smaller than 100 μm or 50 μm. However, when the deformed member is deformed, the deviation from flatness is increased and the parallelism is reduced. Thus, the heat radiation performance is also reduced.

When the heat radiation members and the control terminal are crimped, it is necessary to process metallically the heat radiation member for crimping. This metallic processing may affect the deviation from flatness and the parallelism of the heat radiation member. Thus, the heat radiation performance is also reduced.

Further, it is difficult to select the materials of the heat radiation member and the control terminal. Specifically, it is required for the material of the heat radiation member to have sufficient electric conductivity and heat conductivity. It is required for the material of the control terminal to have mechanical strength, bending performance and/or positioning accuracy of an outer lead. However, by processing the rolled member and/or the metallic plate, the heat radiation member and the control terminal are integrated so that the deformed member is prepared. Accordingly, it is difficult to meet the above requirements. For example, when the heat radiation member is made of pure copper such as Japanese Industrial Standards C1020 having a softening point of 200° C., the Hv hardness of the control terminal becomes insufficient. Thus, stability of the shape of the control terminal and press workability of the control terminal are reduced. Here, it is considered that different materials are prepared, and then, they are crimped. However, this method may affect the metallic processing.

Further, when the semiconductor device is manufactured, a pair of heat radiation members is soldered through the semiconductor chip. In this case, solder wettability and a gravity center position of mounted elements may cause the thickness of the semiconductor device and the parallelism of each heat radiation member to deviate. It is important to maintain the dimensional accuracy. Thus, it is necessary to keep the positioning of the pair of heat radiation members to have predetermined dimensions, i.e., to have a predetermined distance between the heat radiation members. In view of this point, in Japanese Patent No. 3620399, the semiconductor chip is sandwiched between the heat radiation members with keeping the parallelism of the heat radiation surfaces of the pair of heat radiation members. However, in this case, it is required for the heat radiation member to have a complicated shape for keeping the parallelism. Thus, when the shape of the heat radiation member is complicated, the processing may affect the heat radiation member and the control member; and therefore, the shape accuracy of them is reduced.

Thus, it is required to keep parallelism and to reduce deviation from flatness in a pair of heat radiation members.

### SUMMARY OF THE INVENTION

In view of the above-described problem, it is an object of the present disclosure to provide a semiconductor device having a heat radiation member and a semiconductor chip. It is another object of the present disclosure to provide a method for manufacturing a semiconductor device having a heat radiation member and a semiconductor chip.

According to a first aspect of the present disclosure, a method for manufacturing a semiconductor device having a semiconductor chip, first and second heat radiation members and a connection terminal, wherein the first and second heat radiation members sandwich the semiconductor chip so that the first and second heat radiation members radiate heat generated in the semiconductor chip, and wherein the connection terminal connects the semiconductor chip and the first and second heat radiation members, and electrically connects to an external circuit, the method comprising: preparing a plate shaped lead frame having first and second suspended terminals and the connection terminal; bending the first suspended terminal to a first side of the lead frame, and bending the second suspended terminal to a second side of the lead frame so that a distance between the first and second suspended terminals in a direction perpendicular to the lead frame is set to be a predetermined distance; preparing the first heat radiation member to face the first side of the lead frame, and preparing the second heat radiation member to face the second side of the lead frame, wherein each of the first and second heat radiation members is independently prepared from the lead frame; mounting the semiconductor chip on the first heat radiation member to contact a first side of the semiconductor chip and an inner surface of the first heat radiation member, press-contacting the first suspended terminal to the first heat radiation member, and bonding the semiconductor chip together with the connection terminal to the first heat radiation member; and preparing an assembling jig having a base and a cover, mounting the first heat radiation member on the base after the bonding the semiconductor chip together with the connection terminal to the first heat radiation member, arranging the second heat radiation member on the second suspended terminal to contact an inner surface of the second heat radiation member and a mounting surface of the second suspended terminal, pressing the second heat radiation member with the cover toward the base in such a manner that a heat radiation surface of the second heat radiation member is parallel to a heat radiation surface of the first heat radiation member, and bonding a second side of the semiconductor chip and the inner surface of the second heat radiation member under a condition where the second suspended terminal press-contacts the second heat radiation member by a reaction force of a spring function of the second suspended terminal. A distance between the inner surface of the first heat radiation member and the mounting surface of the second suspended terminal is larger than a distance between the inner surface of the first heat radiation member and the second side of the semiconductor chip after the bonding the semiconductor chip together with the connection terminal to the first heat radiation member.

In the above method, it is not necessary to prepare the heat radiation members, which is plastically deformed. Thus, the heat radiation member does not warp, so that the deviation from flatness of the heat radiation members is reduced. Further, by using the reaction force of the suspended terminals, the parallelism of the heat radiation members is improved, so that the dimensional accuracy of the heat radiation surfaces of the heat radiation members is improved.

According to a second aspect of the present disclosure, a semiconductor device includes: a semiconductor chip; first and second heat radiation members for sandwiching the semiconductor chip and radiating heat generated in the semiconductor chip, wherein the first and second heat radiation members are electrically coupled with the semiconductor chip; a connection terminal coupled with each heat radiation member and electrically coupled with an external circuit, wherein the connection terminal is a different body from the first and second heat radiation members; and a resin mold for sealing the first and second heat radiation members and the connection terminal.

In the above device, since the connection terminal is a different body from the first and second heat radiation members, the heat radiation members can be prepared without performing a plastically deformed method. Thus, the dimensional accuracy and the deviation from flatness of the heat radiation members are improved. Thus, dimensional accuracy and positioning accuracy of each element in the device are also improved.

### BRIEF DESCRIPTION OF THE DRAWINGS

The above and other objects, features and advantages of the present invention will become more apparent from the following detailed description made with reference to the accompanying drawings. In the drawings:

FIG. 1A is a plan view showing a semiconductor device according to a first embodiment, FIG. 1B is a transparent view showing the device viewing from IB in FIG. 1A, and FIG. 1C is a cross sectional view showing the device taken along line IC-IC in Fig. C;

FIG. 2A is a plan view explaining a method for manufacturing the device shown in FIG. 1A, FIG. 2B is a side view showing the device viewing from IIB in FIG. 2A, and FIGS. 2C-2G are cross sectional views showing the device taken along lines IIC-IIC, IID-IID, IIE-IIE, IIF-IIF, and IIG-IIG in FIG. 2A respectively;

FIG. 3A is a plan view explaining the method for manufacturing the device, and FIG. 3B is a side view showing the device viewing from IIIB in FIG. 3A;

FIG. 4A is a plan view explaining the method for manufacturing the device, and FIG. 4B is a cross sectional view showing the device taken along line IVB-IVB in FIG. 4A;

FIG. 5A is a plan view explaining the method for manufacturing the device, FIG. 5B is a transparent view showing the device viewing from VB in FIG. 5A, and FIG. 5C is a side view showing the device viewing from VB in FIG. 5A;

FIG. 6A is a plan view explaining the method for manufacturing the device, and FIG. 6B is a transparent view showing the device viewing from VIB in FIG. 6A;

FIG. 7A is a plan view explaining the method for manufacturing the device, FIG. 7B is a side view showing the device viewing from VIIB in FIG. 7A, and FIG. 7C is a cross sectional view showing the device taken along line VIIC-VIIC in FIG. 7A;

FIG. 8A is a plan view explaining a method for manufacturing a semiconductor device according to a second embodiment, and FIG. 8B is a partially enlarged perspective view showing a part VIIIB of the device in FIG. 8A;

FIG. 9 is a partially enlarged perspective view explaining a method for manufacturing a semiconductor device according to a third embodiment;

FIG. 10A is a plan view explaining a method for manufacturing a semiconductor device according to a fourth embodiment, and FIG. 10B is a side view showing the device viewing from XB in FIG. 10A;

FIG. 11 is a cross sectional view showing a semiconductor device according to a fifth embodiment; and

FIG. 12 is a cross sectional view showing a semiconductor device according to a sixth embodiment.

### DETAILED DESCRIPTION OF THE PREFERRED EMBODIMENTS

### First Embodiment

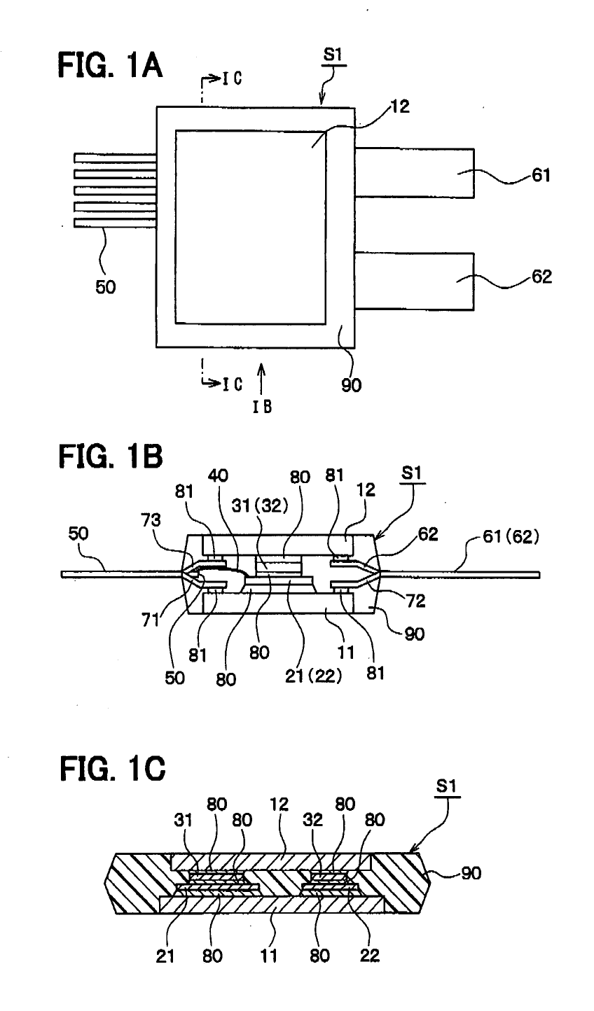

A semiconductor device S1 according to a first embodiment is shown in FIGS. 1A to 1C. The device S1 is suitably used for controlling an inverter of a hybrid vehicle.

In the device S1, a first semiconductor chip 21 is mounted on a first heat radiation member 11, and a second heat radiation member 12 is disposed on the first semiconductor chip 21 with a first heat radiation block 31. A gate electrode of the first semiconductor chip 21 is coupled with a control signal terminal 50 through a gate wire 40. The first radiation member 11 is connected to a first main terminal 61, and the second radiation member 12 is connected to a second main terminal 62.

A second semiconductor chip 22 is mounted on the first heat radiation member 11 such that the first semiconductor chip 21 and the second semiconductor chip 22 are arranged in parallel each other. The second heat radiation member 12 is disposed on the second semiconductor chip 22 with a second heat radiation block 32. Both sides of each chip 21, 22 have electrodes, respectively.

The first semiconductor chip 21 includes, for example, FWD (i.e., free wheel diode) and the like. The second semiconductor chip 22 includes, for example, a power semiconductor element such as an IGBT (insulated gate bipolar transistor) and a thyristor.

The control signal terminal 50 and the first and second main terminals 61, 62 are leads for inputting a signal from an external circuit into the chips 21, 22. The control signal terminal 60 and the first and second main terminals 61, 62 are formed from a lead frame 70 made of heat resistant copper alloy, copper, aluminum, or alloy of them. The lead frame 70 is a plate.

A bonding member 80 is disposed among the first and second heat radiation members 11, 12, the first and second semiconductor chips 21, 22, and the first and second heat radiation blocks 31, 32 so that elements are electrically and thermally coupled each other. Another bonding member 81 is disposed between the first main terminal 61 and the first heat radiation member 11 and between the second main terminal and the second heat radiation member 12 so that the first main terminal 61 is electrically connected to the first heat radiation member 11, and the second main terminal 62 is electrically connected to the second heat radiation member 12. The bonding members 80, 81 are made of solder or conductive adhesive material. In this embodiment, the bonding members 80, 81 are made of tin series solder. Alternatively, the bonding members 80, 81 are made of silver paste.

Each heat radiation member 11, 12 functions as a heat radiation plate for discharging heat generated in the semiconductor chip 21, 22. Thus, the heat radiation member 11, 12 is made of excellent heat conductive material having low resistance such as copper or aluminum. Each heat block 31, 32 conducts the heat generated in the semiconductor chip 21, 22 to the second heat radiation member side. Each heat block 31, 32 is made of pure copper or the like.

The heat radiation members 11, 12 and the heat radiation blocks 31, 32 are formed from a metallic plate by a press working method. Since the plate is merely pressed, processing strain and stress are not substantially formed in the heat radiation members 11, 12 and the heat radiation blocks 31, 32. Thus, the shape accuracy of the heat radiation members 11, 12 and the heat radiation blocks 31, 32 is comparatively high. Further, by maintaining the heat radiation performance of each heat radiation member 11, 12, it is preferred that the parallelism of the heat radiation surface is high. The parallelism is defined as roughness of the heat radiation surface. When the parallelism is high, the roughness is small. Thus, it is preferred that the roughness of the heat radiation surface of each heat radiation member 11, 12 is smaller than 100 μm or 50 μm.

Accordingly, on the top side of each semiconductor chip 21, 22, the heat is discharged through the heat radiation block 31, 32 and the second heat radiation member 12. On the bottom side of each semiconductor chip 21, 22, the heat is discharged through the first heat radiation member 11.

As shown in FIG. 1B, a first suspended terminal 71 is connected to the first heat radiation member 11 on the control signal terminal side. A second suspended terminal 72 is connected to the first heat radiation member 11. The second suspended terminal 72 is disposed opposite to the first suspended terminal 71. A third suspended terminal 73 is connected to the second heat radiation member 12 on the control signal terminal side. The bonding member 81 is disposed between each suspended terminal 71-73 and each heat radiation member 11, 12 so that the suspended terminal 71-73 is bonded to the heat radiation member 11, 12.

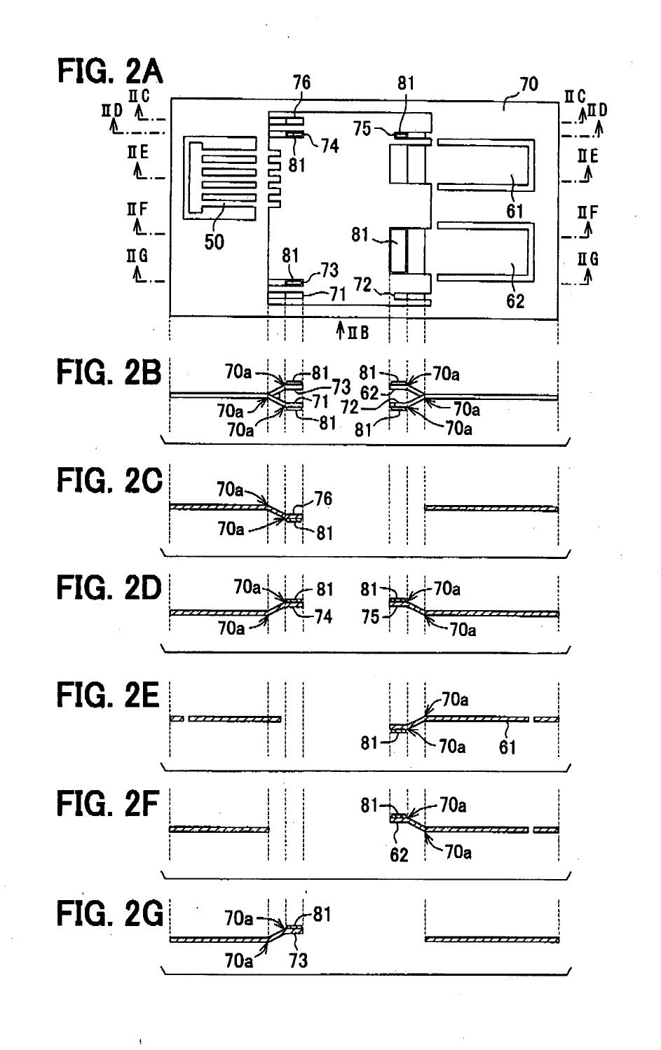

Further, as shown in FIG. 2A, a sixth suspended terminal 76 corresponding to the first suspended terminal 71 is connected to the first heat radiation member 11 on the control signal terminal side. A fourth suspended terminal 74 corresponding to the second suspended terminal 72 is connected to the first heat radiation member 11. A fifth suspended terminal 75 corresponding to the third suspended terminal 73 is connected to the second heat radiation member 12 on the control signal terminal side. The fourth to sixth suspended terminals 74-76 are disposed on one side of the device S1, which is opposite to the first to third suspended terminals 71-73.

A part of each suspended terminal 71-76 is folded in order to maintain the parallelism between the first and second heat radiation members 11, 12 when the device S1 is manufactured. Further, since the suspended terminal 71-76 is merely connected to the heat radiation member 11, 12, the operation of the device S1 is not directly affected. The parallelism is defined as a degree of tilt of one heat radiation surface of the heat radiation members 11, 12 with reference to the other heat radiation surface. When the parallelism is high, the degree of tilt is small.

One side of the first heat radiation member 11, one side of the second heat radiation member 12, a part of the control signal terminal 50, a part of the first main terminal 61 and a part of the second main terminal 62 are exposed from a resin mold 90. Here, the control signal terminal 50 and the first and second main terminals 61, 62 provide a connection terminal.

A method for manufacturing the device S1 is described with reference to FIGS. 2A-7C.

In FIGS. 2A to 2G, a plate shaped lead frame 70 is prepared. Specifically, the control signal terminal 50, the first and second main terminals 61, 62 and the first to sixth suspended terminals 71-76 are formed, i,e., patterned, and coupled each other with a tie bar so that the lead frame 70 is prepared. The lead frame 70 is formed by, for example, a press working method.

Preferably, each suspended terminal 71-76 formed in the lead frame 70 can have a spring function even when the lead frame 70 is disposed under a temperature in a reflow process. In view of this, the lead frame 70 is made of a certain material for securing the spring function of the suspended terminals 71-76. Specifically, the material of the lead frame 70 has a softening point, which is higher than atemperature, at which the suspended terminals 71-76 are bonded to the heat radiation members 11, 12. Thus, it is preferred that the softening point of the lead frame 70 is higher than a reflow temperature. For example, the lead frame 70 is made of copper, aluminum or alloy of them.

When the lead frame 70 and the first and second heat radiation members 11, 12 are bonded, the first to sixth suspended terminals 71-76 control the positioning of each heat radiation member 11, 12 and a distance between the first and second heat radiation members 11, 12, and adjust the parallelism between the heat radiation surfaces of the heat radiation members 11, 12. As shown in FIG. 2A, six suspended terminals 71-76 are formed on the lead frame 70.

As shown in FIG. 2B, each of the main terminals 61, 62 and the suspended terminals 71-76 has a top portion as a bending portion 70a, which is bent. Each bending portion 70a is formed such that a top end of the main terminal 61, 62 or the suspended terminal 71-76 is bent toward one side of the lead frame 70 (i.e., the first heat radiation member side) or the other side of the lead frame 70 (i.e., the second heat radiation member side). FIG. 2B is a transparent view seeing from an arrow IIB in FIG. 2A.

As shown in FIG. 2C, the top portion of the sixth suspended terminal 76 is bent toward the one side of the lead frame 70. As shown in FIG. 2D, the top portion of each of the fourth and fifth suspended terminals 74, 75 is bent toward the other side of the lead frame 70. As shown in FIG. 2E, the control signal terminal 50 is not bent, and the top portion of the first main terminal 61 is bent toward the one side of the lead frame 70. As shown in FIG. 2F, the top portion of the second main terminal 62 is bent toward the other side of the lead frame 70. As shown in FIG. 2G, the top portion of the third suspended terminal 73 is bent toward the other side of the lead frame 70. Here, the top portion of each of the first and second suspended terminals 71, 72 is bent toward the one side of the lead frame 70.

The bending portion 70a of each of the main terminals 61, 62 and the suspended terminals 71-76 is formed such that the top portion of the main terminals 61, 62 or the suspended terminals 71-76 is pressed toward the one side or the other side of the lead frame 70.

A surface treatment is performed on the top portion of each of the main terminals 61, 62 and the suspended terminals 71-76 in order to bond the top portion to the heat radiation member 11, 12. Specifically, the bonding member 81 is formed on the top portion of each of the main terminals 61, 62 and the suspended terminals 71-76. The bonding member 81 is disposed on the top portion such that the bonding member 81 faces the heat radiation member 11, 12. If necessary, whole of the top portion may be coated with a plating nickel film.

The control signal terminal 50 and the main terminals 61, 62 are wires for electrically connecting to an external circuit. Accordingly, the material of control signal terminal 50 and the main terminals 61, 62 has excellent conductivity. It is preferred that the control signal terminal 50 and the main terminals 61, 62 are made of copper, aluminum or alloy of them. When it is required for the control signal terminal 50, the main terminals 61, 62 and the suspended terminals 71-76 to have bendable property and heat resistance, they may be made of alloy or the like having these properties.

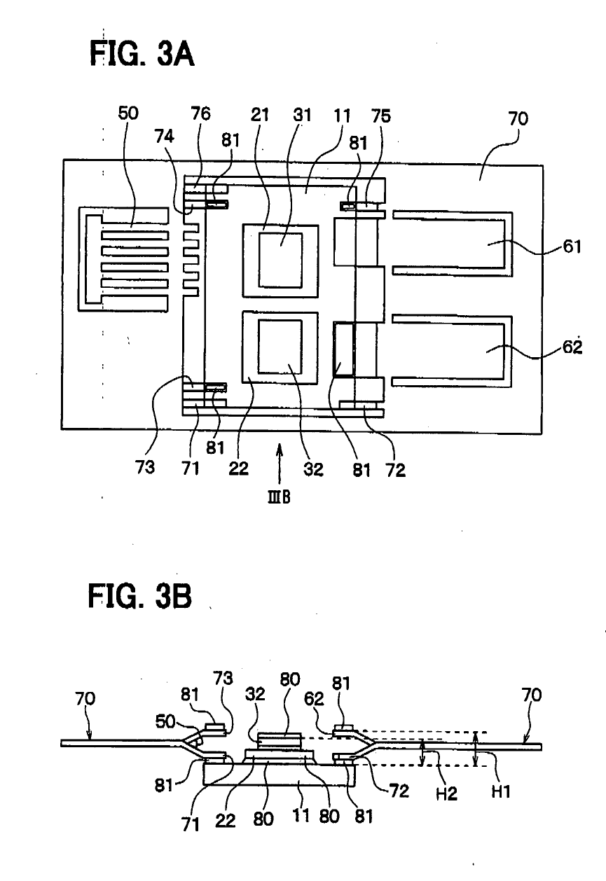

In FIGS. 3A and 3B, the first heat radiation member 11 is mounted on the lead frame 70. First, the first heat radiation member 1 separated from the lead frame 70 is prepared by pressing a metallic plate. The heat radiation surface and the mounting surface of the first heat radiation member 11 are prepared by pressing and punching a rolled member so that a high parallelism is obtained. The semiconductor chips 21, 22 are mounted on the mounting surface of the first heat radiation member 11. Preferably, the first heat radiation member 11 is made of pure copper or aluminum having excellent heat conductivity so that the heat generated in the semiconductor chips 21, 22 is discharged easily. Further, the second heat radiation member 12 is similarly prepared.

A nickel coating may be formed on the surface of the first heat radiation member 11. The first heat radiation member 11 may have a softening point, which is lower than a reflow temperature in a reflow process, as long as the first heat radiation member 11 has sufficient heat conductivity. The second heat radiation member 12 may also have the nickel coating thereon, and have the softening point lower than the reflow temperature. Preferably, the softening point of each of the first and second heat radiation members 11, 12 is lower than a temperature, at which the suspended terminals 71-76 are bonded to the heat radiation members 11, 12.

As shown in FIG. 3A, the first and second semiconductor chips 21, 22 are mounted on the first heat radiation member 11. Further, the first and second heat radiation blocks 31, 32 are mounted on the first and second semiconductor chips 21, 22 with the bonding member 80 therebetween. Furthermore, the bonding member 80 is mounted on the first and second heat radiation blocks 31, 32, and is disposed opposite to the first and second semiconductor chips 21, 22. The bonding member 80 connects the heat radiation blocks 31, 32 and the second heat radiation member 12.

Thus, the first heat radiation member 11 together with the semiconductor chips 21, 22 and the heat radiation blocks 31, 32 mounted thereon is prepared. The lead frame shown in FIG. 2A is arranged on the first heat radiation member 11. Thus, the bonding member 81 disposed around the first, second and sixth suspended terminals 71, 72, 76 and the bonding member 81 disposed around the first main terminal 61 are bonded to the first heat radiation member 11. The positioning between the first heat radiation member 11 and the lead frame 70 is performed by using a carbon jig or the like.

The above lead frame 70 with the first heat radiation member 11 is reflowed at 280° C., for example, so that the bonding member 80 is melt. Thus, the semiconductor chips 21, 22 and the heat radiation blocks 31, 32 are bonded together. Further, the semiconductor chips 21, 22 and the first heat radiation member 11 are bonded together. Furthermore, the first, second and sixth suspended terminals 71, 72, 76, the first main terminal 61 and the first heat radiation member 11 are bonded together.

After the above reflow process, as shown in FIG. 3B, a surface of the first heat radiation member 11, on which the semiconductor chips 21, 22 are mounted, is defined as a reference surface. In this case, the third to fifth suspended terminals 73-75 and the second main terminal 62 are provided by bending the lead frame 70 toward a side opposite to the first heat radiation member 11. One side of each of the third to fifth suspended terminals 73-75 and the second main terminal 62, on which the bonding member 81 is mounted, faces the second heat radiation member 12. The one side of each of the third to fifth suspended terminals 73-75 and the second main terminal 62 is apart from the one side of the first heat radiation block 31 or the second heat radiation block 32, which faces the second heat radiation member 12.

Specifically, a distance between the reference surface of the first heat radiation member 11 and the one side of each of the third to fifth suspended terminals 73-75 is defined as H1. A distance between the reference surface and the one side of the first heat radiation block 31 is defined as H2. The suspended terminals 71-76 and the main terminals 61, 62 are bent from the lead frame 70 so that the distance H1 is larger than the distance H2.

When the lead frame 70 is formed, and the lead frame 70 is bonded to the first heat radiation member 11, the bending portion 70a is formed by bending the suspended terminals 71-76 and the main terminals 61, 62 in order to have the relationship such that the distance H1 is larger than the distance H2.

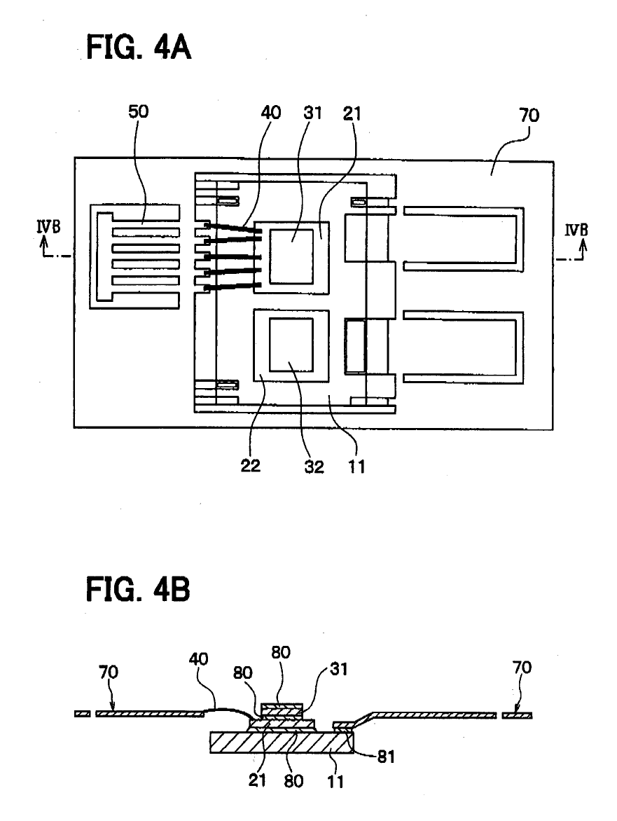

In FIGS. 4A and 4B, the control signal terminal 50 and the gate electrode of the first semiconductor chip 21 are coupled with the gate wire 40. The gate wire 40 is made of, for example, aluminum or a gold wire. In this wire bonding process, the control signal terminal 50 is electrically connected to the first semiconductor chip 21. When an inner lead of the control signal terminal 50 is soldered with the first semiconductor chip 21 through a bump or the like, the control signal terminal 50 and the gate electrode of the first semiconductor chip 21 may be soldered in a process shown in FIGS. 3A and 3B

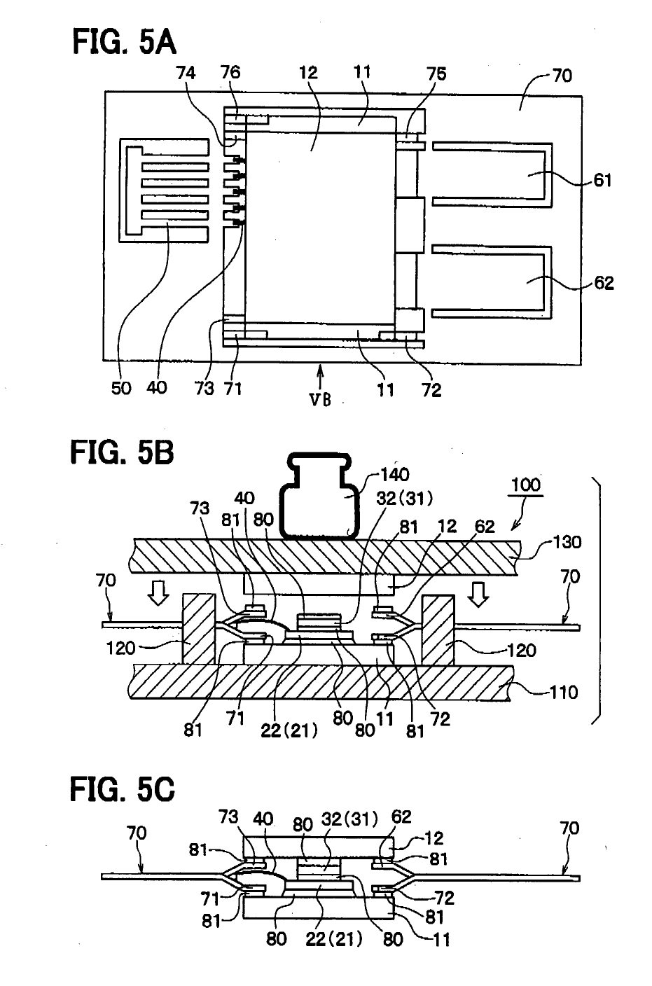

In FIGS. 5A to 5C, the second heat radiation member 12 is mounted on a product shown in FIGS. 4A and 4B. Specifically, the product in FIG. 4A is set in an assembling jig 100 shown in FIG. 5B. The assembling jig 100 includes a base 110 for mounting the first heat radiation member 11 thereon, multiple supports 120 disposed on the main terminal side and the control signal terminal side in the lead frame 70, a cover 130 for pressing the second heat radiation member 12 on the base 110, and a weight portion 140 for applying a load to the cover 130. Each element in the assembling jig 100 is made of material, which has sufficient temperature resistance against the reflow temperature.

One surface of each of the cover 130 and the base 110, which press-contacts the heat radiation members 11, 12, is flattened. Thus, the deviation from flatness in the cover 130 and the base 110 is comparatively small. Multiple supports 120 have the same height from the surface of the base 110, on which the first heat radiation member 11 is mounted. The height of each support 120 defines the distance between the first and second heat radiation members 11, 12 when the lead frame 70 is mounted on the second heat radiation member 12. Thus, the height of the support 120 corresponds to the distance between the heat radiation surfaces of the first and second heat radiation members 11, 12 in the device S1 shown in FIGS. 1B and 1C.

First, the lead frame 70 is mounted on the assembling jig 100 after the process shown in FIGS. 4A to 4B. Then, as shown in FIG. 5B, the second heat radiation member 12 is mounted on the third to fifth suspended terminals 73-75 and the second main terminal 62, and then, the cover 130 presses and contacts the second heat radiation member 12 toward the base 110. The load is applied to the cover 130 by using the weight 140, which is about few tens grams to few hundreds grams.

The top portion of each of the suspended terminals 71-76 and the main terminals 61, 62 has a spring function since the top portion has the bending portion 70a. The elastic force of the spring function generates a reaction force. Specifically, the first, second and sixth suspended terminals 71, 72, 76 and the first main terminal 61, which are bent toward the one side of the lead frame 70, receives the reaction force toward the first heat radiation member side. The third to fifth suspended terminals 73-75 and the second main terminal 62 receives the reaction force toward the second heat radiation member side. Thus, the first heat radiation member 11 is pressed toward the base 110, and the second heat radiation member 12 is pressed toward the cover 130.

Each support 120 has the same height, and the deviation from flatness on the surface of each of the base 110 and the cover 130 is small, the surface which presses the heat radiation members 11, 12. Accordingly, when the cover 130 press-contacts the supports 120, the parallelism between the base 110 and the cover 130 is kept.

Thus, by using the reaction force of the suspended terminals 71-76 and the main terminals 61, 62 in the lead frame 70, the heat radiation members 11, 12 press the base 110 and the cover 130. The parallelism between the heat radiation surfaces of the heat radiation members 11, 12 is kept. The distance between the heat radiation surfaces can be adjusted by the height of the supports 120.

When the lead frame 70 is manufactured, the bending portion 70a of each of the suspended terminals 71-76 and the main terminals 61, 62 is formed under the above described conditions. Thus, by using the spring function of the suspended terminals 71-76 and the main terminals 61, 62, the parallelism between the heat radiation surfaces is kept.

Further, the cover 130 press-contacts the supports 120, and the weight 140 is arranged on the cover 130 so that the load is applied to the cover 130. Then, the lead frame 70 is reflowed at 280° C. The posture and the positioning among the suspended terminals 71-76, the main terminals 61, 62, and the heat radiation members 11, 12 are maintained, and the first, second and sixth suspended terminals 71, 72, 76, the second main terminal 62, the heat radiation blocks 31, 32 and the second heat radiation member 12 are bonded together. Then, the product is removed from the assembling jig 100. Thus, the product shown in FIG. 5C is formed.

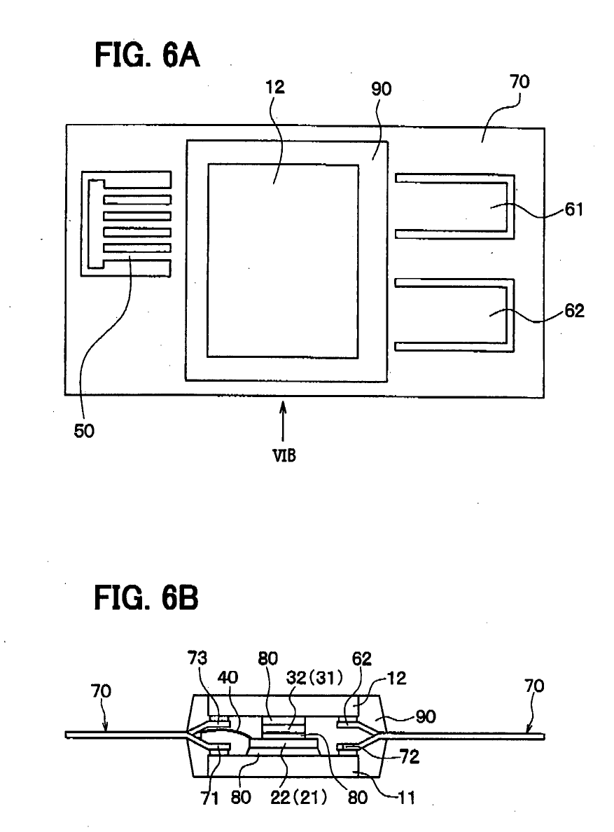

In FIGS. 6A and 6B, the product is sealed with a resin mold. Specifically, the product shown in FIG. 5C is mounted in a die (not shown). Melted resin is poured into the die so that the product is sealed with the resin mold 90. Specifically, the product is sealed such that the other one side of the first heat radiation member 11, the other one side of the second heat radiation member 12, and a part of each main terminal 61, 62 are exposed from the resin mold 90. To increase adhesive force of the resin mold 90, a poly amide film maybe coated on the product.

Thus, the product is molded with the resin mold 90, so that each element is fixed in the resin mold 90 with maintaining the posture and the positioning among the heat radiation members 11, 12, the lead frame 70 and the like.

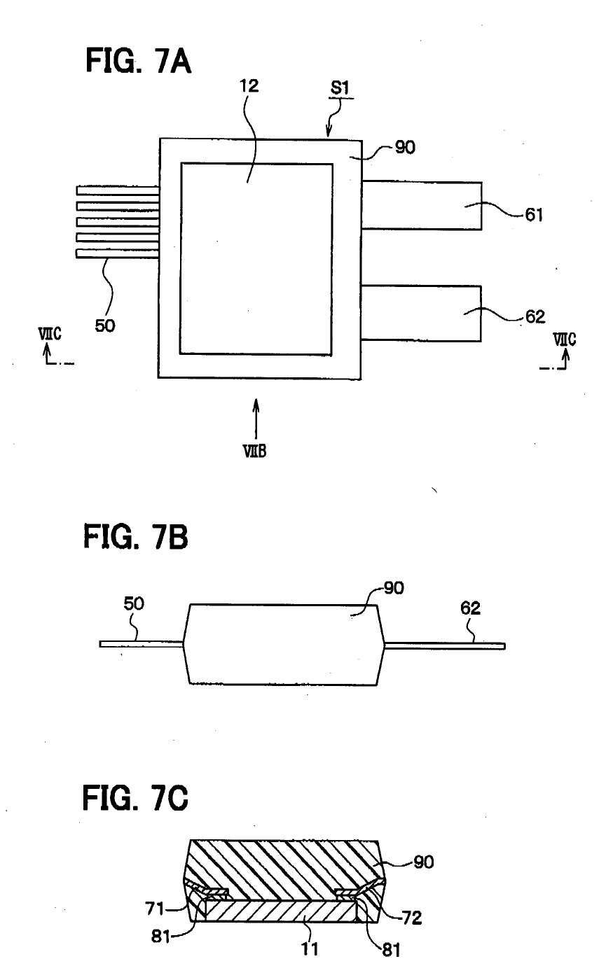

In FIGS. 7A to 7C, unnecessary portion of the product is removed. Specifically, unnecessary portion of the lead frame 70 other than the control signal terminal 50 and the main terminals 61, 62 and the tie bar are cut. Thus, the product shown in FIGS. 7A and 7B is obtained.

As shown in FIG. 7C, the top ends of the first and second suspended terminals 71, 72 are disposed in the resin mold 90. However, the suspended terminals 71, 72 are only connected to the first heat radiation member 11, and they 71, 72 do not have electrical conduction with other elements. Thus, although the suspended terminals 71, 72 are not removed from the resin mold 90, there is no difficulty. Similarly, the third to sixth suspended terminals 73-76 are also disposed in the resin mold 90. Thus, the device S1 is completed.

Then, electrical conduction test and appearance test of the device S1 is performed. After that, the device S1 is shipped.

In this embodiment, the lead frame 70 and the first and second heat radiation members 11, 12 are independently prepared. Further, by using the spring function of the suspended terminals 71-76 formed in the lead frame 70, the device S1 is manufactured. In this case, it is not necessary to plastically deform the heat radiation member 11, 12. Thus, the heat radiation member 11, 12 is prepared without including a processing strain. Accordingly, the heat radiation member 11, 12 has no warpage caused by the processing strain. The deviation from flatness of each heat radiation member 11, 12 is improved.

Further, since the top portions of the suspended terminals 71-76 and the main terminals 61, 62 are bent, by using the reaction force of the suspended terminals 71-76 and the main terminals 61, 62, the heat radiation members 11, 12 press-contact the base 110 and the cover 130, which are arranged to be in parallel each other by using the supports 120. Thus, the parallelism between the heat radiation surfaces is maintained. Accordingly, the top portions of the suspended terminals 71-76 and the main terminals 61, 62 are bent so that they have the spring function. The elastic force of the spring function provides to maintain the parallelism between the heat radiation surfaces.

Thus, the parallelism between the first and second heat radiation members 11, 12 is improved, and further, the deviation from flatness on the heat radiation surfaces is improved.

### Second Embodiment

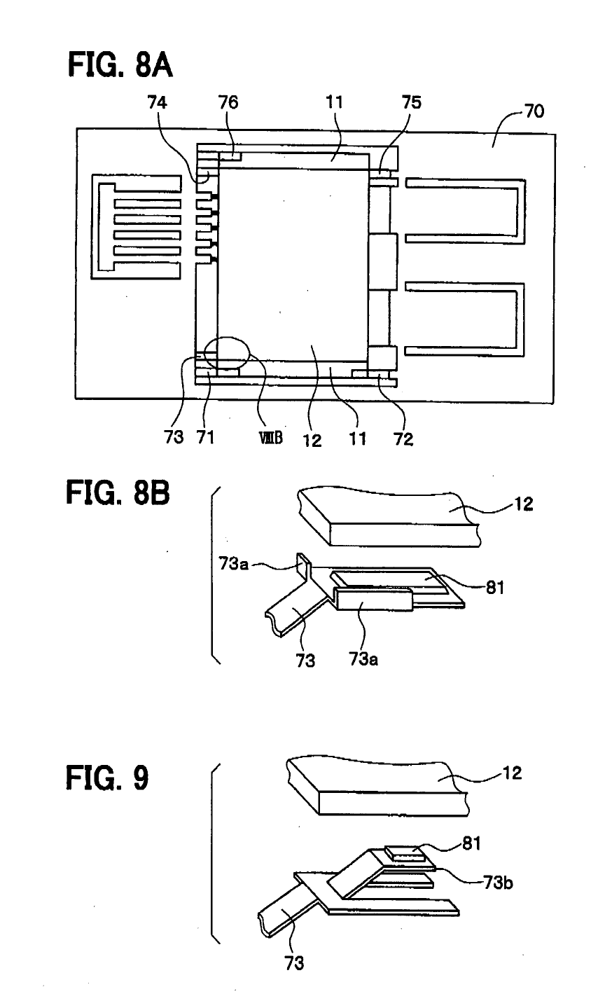

FIGS. 8A and 8B show a semiconductor device according to a second embodiment. Specifically, FIGS. 8A and 8B shows the product after the process shown in FIGS. 5A to 5C. FIG. 8B shows the third suspended terminal 73 and the second heat radiation member 12, which are disassembled.

As shown in FIG. 8B, the third suspended terminal 73 has the top portion with a sidewall 73a, which guides to determine the position of the second heat radiation member 12. The fourth and fifth suspended terminals 74, 75 have similar sidewalls, respectively, so that the sidewalls guide the positioning of the second heat radiation member 12.

Since each suspended terminal 73-75 has the sidewall 73a, the second heat radiation member 12 can be positioned appropriately without using a positioning jig. This sidewall 73a is formed together with forming the suspended terminals 73-75 from the lead frame 70 by a press working method.

The first, second and sixth suspended terminals 71, 72, 76 for connecting to the first heat radiation member 11 may have sidewalls similar to the sidewall 73a shown in FIG. 8B. In this case, the first heat radiation member 11 is easily positioned by using the sidewalls of the suspended terminals 71, 72, 76.

### Third embodiment

FIG. 9 is a partially enlarged view showing the third suspended terminal 73 and the second heat radiation member 12, which are disassembled. The third suspended terminal 73 includes a protrusion 73b, which protrudes from the top portion of the third suspended terminal 73 toward the second heat radiation member side. The protrusion 73b is formed to press-work the top portion of the third suspended terminal 73. The bonding member 81 such as a solder member is disposed on the protrusion 73b. Since the third suspended terminal 73 has the protrusion 3b disposed on the top portion thereof, and the bonding member 81 is disposed on the protrusion 73b, excess bonding member 81 does not move from the top portion of the third suspended terminal 73 when the second heat radiation member 12 is reflowed. When the bonding member 81 is disposed on the protrusion 73b, expansion of the bonding member 81 is limited. Further, the other suspended terminals 71-72, 74-76 may have protrusions disposed on the top portions thereof.

### Fourth Embodiment

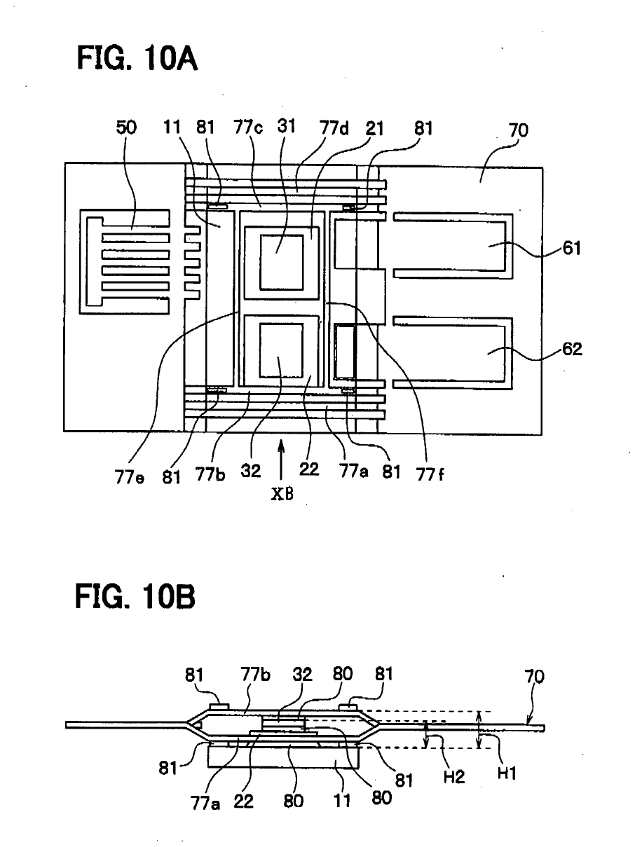

FIGS. 10A and 10B show the lead frame 70. In the lead frame 70, the first suspended terminal 71 and the second suspended terminal 72 are connected so that a seventh suspended terminal 77a is formed. Further, the top portion of the third suspended terminal 73 is extended toward the second main terminal side. Thus, an eighth suspended terminal 77b is formed. Furthermore, the fourth suspended terminal 74 and the fifth suspended terminal 75 are connected so that a ninth suspended terminal 77c is formed. The top portion of the sixth suspended terminal 76 is extended toward the first main terminal side so that a tenth suspended terminal 77d is formed. Further, the eighth suspended terminal 77b and the ninth suspended terminal 77c are coupled with connection bars 77e, 77f.

In the lead frame 70, the shape of each of the eighth suspended terminal 77b and the ninth suspended terminal 77c is maintained by forming the eighth and ninth suspended terminals 77b, 77c and the connection bars 77e, 77f to connect the control signal terminal side and the main terminals side. The lead frame 70 is formed by a press-working method or the like. Thus, the lead frame 70 may be used for the semiconductor device S1.

Although the device S1 includes the seventh and eighth suspended terminals 77a, 77b, the positional relationship between the first heat radiation member 11 and the seventh and eighth suspended terminals 77a, 77b shown in FIG. 10B is similar to the first embodiment.

### Fifth Embodiment

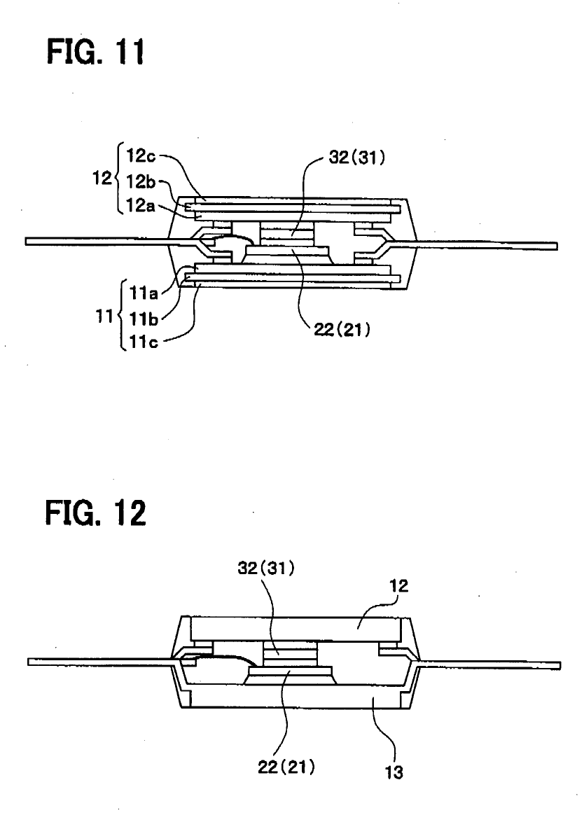

FIG. 11 shows a semiconductor device S1 according to a fifth embodiment. In the device S1, the first heat radiation member 11 has a pair of metallic plates 11a, 11c and an insulation plate 11b, which is sandwiched between the metallic plates 11a, 11c. Further, the second heat radiation member 12 has a pair of metallic plates 12a, 12c and an insulation plate 12b, which is sandwiched between the metallic plates 12a, 12c. The metallic plates 11a, 11c, 12a, 12c and the insulation plate 11b, 12b are bonded together by using a brazing method, an active-metal method or the like.

When the device S1 is mounted on an external circuit board or the like, the metallic plate 11c, 12c exposed from the resin mold 90 is insulated from the metallic plate 11a, 12a disposed in the resin mold 90 by the insulation plate 11b, 12b. Thus, the device S1 is electrically insulated from the external circuit board. Although the first and second heat radiation members 11, 12 include the insulation plates 11b, 12b, the first and second heat radiation members 11, 12 may include insulation resin layers.

Further, each heat radiation members 11, 12 may be formed from two layers, which are composed of the metallic plate 11a, 12a and the insulation plate 11b, 12b. Further, each heat radiation members 11, 12 may be formed from two layers, which are composed of the metallic plate 11a, 12a and the insulation resin layer.

### Sixth Embodiment

FIG. 12 shows a semiconductor device S1 according to a sixth embodiment. In the device, the first heat radiation member 11 is provided by a specific shaped member 13, in which the first main terminal 61 and the first, second and sixth suspended terminals 71, 72, 76 are integrated. Here, since the first heat radiation member 11 is provided by the specific shaped member 13, it is required for the first heat radiation member 11 to maintain the deviation from flatness of the heat radiation surface in a predetermined range. Alternatively, the second heat radiation member 12 may be provided by the specific shaped member 13.

(Modifications)

The device S1 may not have the heat radiation block 31, 32. In this case, when the lead frame 70 is mounted in the assembling jig 100, the suspended terminals 71-76 and the main terminals 61, 62 are formed such that a distance between the reference surface of the first heat radiation member 11 and the surface of each of the suspended terminals 73-75 and the second main terminal 62 is larger than a distance between the reference surface of the first heat radiation member 11 and the surface of each semiconductor chip 21, 22. Here, the distance between the reference surface and the surface of each of the suspended terminals 73-75 and the second main terminal 62 corresponds to the distance H1, and the distance between the reference surface and the surface of each semiconductor chip 21, 22 corresponds to the distance H2. The surface of each of the suspended terminals 73-75 and the second main terminal 62 faces the second heat radiation member 12, and the surface of each semiconductor chip 21, 22 faces the second heat radiation member 12. Further, the number of the suspended terminals 71-76 may be one or more.

Each suspended terminal 71-78 includes the bending portion 70a shown in FIG. 2A to 2G Alternatively, the shape of each suspended terminals 71-76 may have another shape. For example, the top portion of each suspended terminals 71-76 may be bent. Specifically, the top portion may have spring function, so that the top portion of each suspended terminals 71-76 attaches to the heat radiation member 11, 12 by using a reaction force of the spring function when the heat radiation member 11, 12 press-contacts the top portion.

The suspended terminal 71-76 and the heat radiation member 11, 12 are coupled with the bonding member 81. Alternatively, the suspended terminal 71-76 may merely contact or press-contact the heat radiation member 11, 12. In this case, the heat radiation members 11, 12 can be supported by the reaction force of the spring function of the suspended terminals 71-76. Here, the suspended terminals 71-76 directly contact the heat radiation members 11, 12 without using the bonding member 81.

The above disclosure has the following aspects.

According to a first aspect of the present disclosure, a method for manufacturing a semiconductor device having a semiconductor chip, first and second heat radiation members and a connection terminal, wherein the first and second heat radiation members sandwich the semiconductor chip so that the first and second heat radiation members radiate heat generated in the semiconductor chip, and wherein the connection terminal connects the semiconductor chip and the first and second heat radiation members, and electrically connects to an external circuit, the method comprising: preparing a plate shaped lead frame having first and second suspended terminals and the connection terminal; bending the first suspended terminal to a first side of the lead frame, and bending the second suspended terminal to a second side of the lead frame so that a distance between the first and second suspended terminals in a direction perpendicular to the lead frame is set to be a predetermined distance; preparing the first heat radiation member to face the first side of the lead frame, and preparing the second heat radiation member to face the second side of the lead frame, wherein each of the first and second heat radiation members is independently prepared from the lead frame; mounting the semiconductor chip on the first heat radiation member to contact a first side of the semiconductor chip and an inner surface of the first heat radiation member, press-contacting the first suspended terminal to the first heat radiation member, and bonding the semiconductor chip together with the connection terminal to the first heat radiation member; and preparing an assembling jig having a base and a cover, mounting the first heat radiation member on the base after the bonding the semiconductor chip together with the connection terminal to the first heat radiation member, arranging the second heat radiation member on the second suspended terminal to contact an inner surface of the second heat radiation member and a mounting surface of the second suspended terminal, pressing the second heat radiation member with the cover toward the base in such a manner that a heat radiation surface of the second heat radiation member is parallel to a heat radiation surface of the first heat radiation member, and bonding a second side of the semiconductor chip and the inner surface of the second heat radiation member under a condition where the second suspended terminal press-contacts the second heat radiation member by a reaction force of a spring function of the second suspended terminal. A distance between the inner surface of the first heat radiation member and the mounting surface of the second suspended terminal is larger than a distance between the inner surface of the first heat radiation member and the second side of the semiconductor chip after the bonding the semiconductor chip together with the connection terminal to the first heat radiation member.

In the above method, it is not necessary to prepare the heat radiation members, which is plastically deformed. Thus, the heat radiation member does not warp, so that the deviation from flatness of the heat radiation members is reduced. Further, by using the reaction force of the suspended terminals, the parallelism of the heat radiation members is improved, so that the dimensional accuracy of the heat radiation surfaces of the heat radiation members is improved.

Alternatively, the bonding the semiconductor chip together with the connection terminal to the first heat radiation member may include bonding the first suspended terminal to the first heat radiation member. The bonding the second side of the semiconductor chip and the inner surface of the second heat radiation member includes bonding the second suspended terminal to the second heat radiation member, and the lead frame is made of a material having a softening point, which is higher than a temperature at the bonding the first suspended terminal to the first heat radiation member and a temperature at the bonding the second suspended terminal to the second heat radiation member. In this case, the lead frame is not softened when the suspended terminals are bonded to the heat radiation members. Thus, the mechanical strength of the lead frame is improved. Accordingly, when the lead frame is bonded to the second heat radiation member, the reaction force of the suspended terminals is improved.

Alternatively, the bonding the semiconductor chip together with the connection terminal to the first heat radiation member may include bonding the first suspended terminal to the first heat radiation member. The bonding the second side of the semiconductor chip and the inner surface of the second heat radiation member includes bonding the second suspended terminal to the second heat radiation member. The first heat radiation member is made of a material having a first softening point, and the second heat radiation member is made of a material having a second softening point, and the first and second softening points are lower than a temperature at the bonding the first suspended terminal to the first heat radiation member and a temperature at the bonding the second suspended terminal to the second heat radiation member.

Alternatively, the method may further includes: sealing the semiconductor chip with a resin mold in such a manner that the heat radiation surface of the first heat radiation member, the heat radiation surface of the second heat radiation member and a part of the connection terminal are exposed from the resin mold after the bonding the second side of the semiconductor chip and the inner surface of the second heat radiation member; and removing a part of the lead frame other than the part of the connection terminal after the sealing the semiconductor chip with the resin mold, wherein the part of the lead frame is exposed from the resin mold. Further, the lead frame may further include an opening for accommodating the semiconductor chip. The mounting the semiconductor chip on the first heat radiation member includes mounting the lead frame on the first heat radiation member in such a manner that the semiconductor chip is disposed in the opening of the lead frame. The bonding the semiconductor chip together with the connection terminal to the first heat radiation member further includes bonding the connection terminal to the semiconductor chip with a wire. The bonding the second side of the semiconductor chip and the inner surface of the second heat radiation member further includes bonding the connection terminal to the second heat radiation member. Furthermore, the lead frame may further include a tie bar for connecting among the first and second suspended terminals and the connection terminal, and in the removing a part of the lead frame other than the part of the connection terminal, the tie bar is removed from the lead frame so that the first and second suspended terminals and the connection terminal remain in the semiconductor device. Further, after the tie bar is removed from the lead frame, the first and second suspended terminals and the another part of the connection terminal may be independently disposed in the resin mold, and the first and second suspended terminals may be isolated from the semiconductor chip and the connection terminal.

According to a second aspect of the present disclosure, a semiconductor device includes: a semiconductor chip; first and second heat radiation members for sandwiching the semiconductor chip and radiating heat generated in the semiconductor chip, wherein the first and second heat radiation members are electrically coupled with the semiconductor chip; a connection terminal coupled with each heat radiation member and electrically coupled with an external circuit, wherein the connection terminal is a different body from the first and second heat radiation members; and a resin mold for sealing the first and second heat radiation members and the connection terminal.

In the above device, since the connection terminal is a different body from the first and second heat radiation members, the heat radiation members can be prepared without performing a plastically deformed method. Thus, the dimensional accuracy and the deviation from flatness of the heat radiation members are improved. Thus, dimensional accuracy and positioning accuracy of each element in the device are also improved.

Alternatively, the semiconductor device may further include first and second suspended terminals for maintaining a positioning relationship between the first and second heat radiation members. The first suspended terminal is disposed on the inner surface of the first heat radiation member, and the second suspended terminal is disposed on the inner surface of the second heat radiation member. Further, each suspended terminal may be sealed with the resin mold, and each suspended terminal may have an end, which is a tie-bar cut end at an edge of the resin mold. Further, each suspended terminal may be made of a material having a softening point, which is higher than a bonding temperature of each heat radiation member to the semiconductor chip, a bonding temperature of each heat radiation member to the suspended terminal, or a bonding temperature of each heat radiation member to the connection terminal. Further, each heat radiation member may have a softening point, which is lower than a bonding temperature of the heat radiation member to the suspended terminal. Further, the second suspended terminal may have a mounting surface, which contacts the inner surface of the second heat radiation member, and the semiconductor chip may have a first side contacting the inner surface of the first heat radiation member and a second side contacting the inner surface of the second heat radiation member. A distance between the inner surface of the first heat radiation member and the mounting surface of the second suspended terminal is larger than a distance between the inner surface of the first heat radiation member and the second side of the semiconductor chip. Furthermore, the first suspended terminal may include a bending portion, which is bent toward the inner surface of the first heat radiation member. The second suspended terminal includes a bending portion, which is bent toward the inner surface of the second heat radiation member. The bending portion of the first suspended terminal provides a spring function for press-contacting the first heat radiation member. The bending portion of the second suspended terminal provides a spring function for press-contacting the second heat radiation member. Furthermore, the first and second suspended terminals may be sealed with the resin mold. The first suspended terminal has one end contacting the first heat radiation member and an opposite end. The opposite end of the first suspended terminal is a tie-bar cut end. The second suspended terminal has one end contacting the second heat radiation member and an opposite end. The opposite end of the second suspended terminal is a tie-bar cut end.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. A method for manufacturing a semiconductor device having a semiconductor chip, first and second heat radiation members and a connection terminal, wherein the first and second heat radiation members sandwich the semiconductor chip so that the first and second heat radiation members radiate heat generated in the semiconductor chip, and wherein the connection terminal connects the semiconductor chip and the first and second heat radiation members, and electrically connects to an external circuit, the method comprising:
preparing a plate shaped lead frame having first and second Suspended terminals and the connection terminal;
bending the first suspended terminal to a first side of the lead frame, and bending the second suspended terminal to a second side of the lead frame so that a distance between the first and second suspended terminals in a direction perpendicular to the lead frame is set to be a predetermined distance;
preparing the first heat radiation member to face the first side of the lead frame, and preparing the second heat radiation member to face the second side of the lead frame, wherein each of the first and second heat radiation members is independently prepared from the lead frame;
mounting the semiconductor chip on the first heat radiation member to contact a first side of the semiconductor chip and an inner surface of the first heat radiation member, press-contacting the first suspended terminal to the first heat radiation member, and bonding the semiconductor chip together with the connection terminal to the first heat radiation member; and
preparing an assembling jig having a base and a cover, mounting the first heat radiation member on the base after the bonding the semiconductor chip together with the connection terminal to the first heat radiation member, arranging the second heat radiation member on the second suspended terminal to contact an inner surface of the second heat radiation member and a mounting surface of the second suspended terminal, pressing the second heat radiation member with the cover toward the base in such a manner that a heat radiation surface of the second heat radiation member is parallel to a heat radiation surface of the first heat radiation member, and bonding a second side of the semiconductor chip and the inner surface of the second heat radiation member under a condition where the second suspended terminal press-contacts the second heat radiation member by a reaction force of a spring function of the second suspended terminal, wherein
a distance between the inner surface of the first heat radiation member and the mounting surface of the second suspended terminal is larger than a distance between the inner surface of the first heat radiation member and the second side of the semiconductor chip after the bonding the semiconductor chip together with the connection terminal to the first heat radiation member.

2. The method according to claim 1, wherein
the assembling jig further includes a plurality of supports having a same height from a surface of the base, and
the bonding the second side of the semiconductor chip and the inner surface of the second heat radiation member includes press-contacting the cover to the supports in such a manner that the ba se and the cover sandwich the first and second heat radiation members and the lead frame.

3. The method according to claim 1, wherein
the bending the first and second suspended terminals includes forming a sidewall of the first or second suspended terminal, and
the sidewall contacts the first or second heat radiation member for positioning the first or second heat radiation member in the mounting the semiconductor chip on the first heat radiation member or in the arranging the second heat radiation me member on the second suspended terminal.

4. The method according to claim 1, wherein
the bending the first and second suspended terminals includes forming a protrusion of the first or second suspended terminal,
the protrusion is disposed on a top portion of the first or second suspended terminal, and
the protrusion contacts the first or second heat radiation member in the mounting the semiconductor chip on the first heat radiation member or in the arranging the second heat radiation member on the second suspended terminal.

5. The method according to claim 1, wherein
the bonding the semiconductor chip together with the connection terminal to the first heat radiation member includes bonding the first suspended terminal to the first heat radiation member,
the bonding the second side of the semiconductor chip and the inner surface of the second heat radiation member includes bonding the second suspended terminal to the second heat radiation member, and
the lead frame is made of a material having a softening point, which is higher than a temperature at the bonding the first suspended terminal to the first heat radiation member and a temperature at the bonding the second suspended terminal to the second heat radiation member.

6. The method according to claim 1, wherein
the bonding the semiconductor chip together with the connection terminal to the first heat radiation member includes bonding the first suspended terminal to the first heat radiation member,
the bonding the second side of the semiconductor chip and the inner surface of the second heat radiation member includes bonding the second suspended terminal to the second heat radiation member,
the first heat radiation member is made of a material having a first softening point, and the second heat radiation member is made of a material having a second softening point, and
the first and second softening points are lower than a temperature at the bonding the first suspended terminal to the first heat radiation member and a temperature at the bonding the second suspended terminal to the second heat radiation member.

7. The method according to claim 1, wherein
the first suspended terminal includes a plurality of first suspended terminal portions, and
the bonding the semiconductor chip together with the connection terminal to the first heat radiation member includes bonding a part of or all of the first suspended terminal portions to the first heat radiation member.

8. The method according to claim 7, wherein
in the bonding the part of or all of the first suspended terminal portions to the first heat radiation member, the part of or all of the first suspended terminal portions are bonded to the first heat radiation member with a bonding member.

9. The method according to claim 8, wherein
the semiconductor chip is bonded to the first heat radiation member with the bonding member.

10. The method according to claim 8, wherein
the bonding member has a melting point, which is equal to or lower than a melting point of another bonding member between the semiconductor chip and the first heat radiation member.

11. The method according to claim 1, wherein
the second suspended terminal includes a plurality of second suspended terminal portions, and
the bonding the second side of the semiconductor chip and the second heat radiation member includes bonding a part of or all of the second suspended terminal portions to the second heat radiation member.

12. The method according to claim 11, wherein
in the bonding the part of or all of the second suspended terminal portions to the second heat radiation member, the part of or all of the second suspended terminal portions are bonded to the second heat radiation member with a bonding member.

13. The method according to claim 12, wherein
the semiconductor chip is bonded to the second heat radiation member with the bonding member.

14. The method according to claim 12, wherein
the bonding member has a melting point, which is equal to or lower than a melting point of another bonding member between the semiconductor chip and the second heat radiation member.

15. The method according to claim 1, further comprising:
sealing the semiconductor chip with a resin mold in such a manner that the heat radiation surface of the first heat radiation member, the heat radiation surface of the second heat radiation member and a part of the connection terminal are exposed from the resin mold after the bonding the second side of the semiconductor chip and the inner surface of the second heat radiation member; and
removing a part of the lead frame other than the part of the connection terminal after the sealing the semiconductor chip with the resin mold, wherein the part of the lead frame is exposed from the resin mold.

16. The method according to claim 15, wherein
the lead frame further includes an opening for accommodating the semiconductor chip,
the mounting the semiconductor chip on the first heat radiation member includes mounting the lead frame on the first heat radiation member in such a manner that the semiconductor chip is disposed in the opening of the lead frame,
the bonding the semiconductor chip together with the connection terminal to the first heat radiation member further includes bonding the connection terminal to the semiconductor chip with a wire, and
the bonding the second side of the semiconductor chip and the inner surface of the second heat radiation member further includes bonding the connection terminal to the second heat radiation member.

17. The method according to claim 16, wherein
the lead frame further includes a tie bar for connecting among the first and second suspended terminals and the connection terminal, and
in the removing a part of the lead frame other than the part of the connection terminal, the be bar is removed from the lead frame so that the first and second suspended terminals and the connection terminal remain in the semiconductor device.

18. The method according to claim 17, wherein
after the tie bar is removed from the lead frame, the first and second suspended terminals and another part of the connection terminal are independently disposed in the resin mold, and
the first and second suspended terminals are isolated from the semiconductor chip and the connection terminal.

19. The method according to claim 1, wherein
the first heat radiation member includes a pair of metallic plates and an insulation plate, which is sandwiched between the metallic plates, and
the second heat radiation member includes a pair of metallic plates and an insulation plate, which is sandwiched between the metallic plates.

20. A semiconductor device comprising:
a semiconductor chip;
first and second heat radiation members for sandwiching the semiconductor chip and radiating heat generated in the semiconductor chip, wherein the first and second heat radiation members are electrically coupled with the semiconductor chip;
a connection terminal coupled with each heat radiation member and electrically coupled with an external circuit, wherein the connection terminal is a different body from the first and second heat radiation members; and
a resin mold for sealing the first and second heat radiation members and the connection terminal.

21. The semiconductor device according to claim 20, wherein
the connection terminal is bonded to an inner surface of the first heat radiation member, and bonded to an inner surface of the second heat radiation member, and
the inner surface of the first heat radiation member faces the inner surface of the second heat radiation member.

22. The semiconductor device according to claim 20, further comprising:
first and second suspended terminals for maintaining a positioning relationship between the first and second heat radiation members, wherein
the first suspended terminal is disposed on the inner surface of the first heat radiation member, and
the second suspended terminal is disposed on the inner surface of the second heat radiation member.

23. The semiconductor device according to claim 22, wherein
each suspended terminal includes a sidewall,
the sidewall of the first suspended terminal contacts the first heat radiation member for positioning the first heat radiation member, and
the sidewall of the second suspended terminal contacts the second heat radiation member for positioning the second heat radiation member.

24. The semiconductor device according to claim 22, wherein
each suspended terminal includes a protrusion, which is disposed on a top portion of the suspended terminal,
the protrusion of the first suspended terminal contacts the inner surface of the first heat radiation member, and
the protrusion of the second suspended terminal contacts the inner surface of the second heat radiation member.

25. The semiconductor device according to claim 22, wherein
each suspended terminal includes a bending portion,
the bending portion of the first suspended terminal is bent toward the inner surface of the first heat radiation member, and
the bending portion of the second suspended terminal is bent toward the inner surface of the second heat radiation member.

26. The semiconductor device according to claim 22, wherein
each suspended terminal includes a straight-line portion,
the straight-line portion of the first suspended terminal extends from one side of the first heat radiation member to an opposite side of the first heat radiation member,
the straight-line portion of the first suspended terminal press-contacts the first heat radiation member,
the straight-line portion of the second suspended terminal extends from one side of the second heat radiation member to an opposite side of the second heat radiation member, and
the straight-line portion of the second suspended terminal press-contacts the second heat radiation member.

27. The semiconductor device according to claim 22, wherein
the first suspended terminal is bonded to the first heat radiation member with a bonding member, and
the second suspended terminal is bonded to the second heat radiation member with the bonding member.

28. The semiconductor device according to claim 22, wherein
each suspended terminal is sealed with the resin mold, and
each suspended terminal has an end, which is a tie-bar cut end at an edge of the resin mold.

29. The semiconductor device according to claim 22, wherein
each suspended terminal is made of a material having a softening point, which is higher than a bonding temperature of each heat radiation member to the semiconductor chip, a bonding temperature of each heat radiation member to the suspended terminal, or a bonding temperature of each heat radiation member to the connection terminal.

30. The semiconductor device according to claim 22, wherein
each heat radiation member has a softening point, which is lower than a bonding temperature of the heat radiation member to the suspended terminal.

31. The semiconductor device according to claim 22, wherein
each heat radiation member is made of pure copper.

32. The semiconductor device according to claim 22, wherein
the suspended terminals and the connection terminal are made of copper alloy.

33. The semiconductor device according to claim 22, wherein
the second suspended terminal has a mounting surface, which contacts the inner surface of the second heat radiation member,
the semiconductor chip has a first side contacting the inner surface of the first heat radiation member and a second side contacting the inner surface of the second heat radiation member, and
a distance between the inner surface of the first heat radiation member and the mounting surface of the second suspended terminal is larger than a distance between the inner surface of the first heat radiation member and the second side of the semiconductor chip.

34. The semiconductor device according to claim 33, wherein
the first suspended terminal includes a bending portion, which is bent toward the inner surface of the first heat radiation member,
the second suspended terminal includes a bending portion, which is bent toward the inner surface of the second heat radiation member,
the bending portion of the first suspended terminal provides a spring function for press-contacting the first heat radiation member, and
the bending portion of the second suspended terminal provides a spring function for press-contacting the second heat radiation member.

35. The semiconductor device according to claim 34, wherein
the first and second suspended terminals are sealed with the resin mold,
the first suspended terminal has one end contacting the first heat radiation member and an opposite end,
the opposite end of the first suspended terminal is a tie-bar cut end,
the second suspended terminal has one end contacting the second heat radiation member and an opposite end, and
the opposite end of the second suspended terminal is a tie-bar cut end.

36. The semiconductor device according to claim 20, wherein
each heat radiation member includes a metallic plate and an insulation plate, which are stacked each other.

37. The semiconductor device according to claim 20, wherein
each heat radiation member includes a pair of metallic plates and an insulation plate, and
the insulation plate is sandwiched between the metallic plates.

38. The semiconductor device according to claim 27, wherein
the first heat radiation member is bonded to the semiconductor chip with a second bonding member, and
the second bonding member is made of a same material as the bonding member between the first suspended terminal and the first heat radiation member.
